(19) United States
(12) Patent Application Publication
(10) Pub. No.: US 2014/0061965 A1
(43) Pub. Date: Mar. 6, 2014

(54) RADIATION PROTECTION MATERIAL USING GRANULATED VULCANIZED RUBBER, METAL AND BINDER

(71) Applicant: Colorado Seminary, Denver, CO (US)

(72) Inventor: Zeev Shayer, Littleton, CO (US)

(73) Assignee: Colorado Seminary, Denver, CO (US)

(21) Appl. No.: 14/028,264

(22) Filed: Sep. 16, 2013

Related U.S. Application Data
(62) Division of application No. 12/645,216, filed on Dec. 22, 2009, now abandoned.
Application No. 12/645,216 is a continuation-in-part of application No. 11/628,489, filed on Dec. 4, 2006, now abandoned.

(51) Int. Cl. H05K 13/00

(52) U.S. Cl. CPC H05K 13/00
USPC 264/115

(57) ABSTRACT

A radiation shielding material contains ground scrap tire rubber, granulated iron or other metals of moderate cost, and a suitable binder, such as polyurethane or asphalt. The rubber particles can also have a metallic coating.

### RELATED APPLICATIONS

The present application is a division of the Applicant's co-pending U.S. patent application Ser. No. 12/645,216, entitled “Radiation Protection Material Using Granulated Vulcanized Rubber, Metal And Binder,” filed on Dec. 22, 2009, which is a continuation-in-part of U.S. patent application Ser. No. 11/628,489, filed on Dec. 4, 2006, which claimed the benefit of PCT/US2005/019351, filed on Jun. 2, 2005, which claimed the benefit of U.S. Provisional Patent Application 60/577,441, filed on Jun. 4, 2004.

### BACKGROUND OF THE INVENTION

1. Field of the Invention

The present invention relates generally to the field of radiation shielding materials. More specifically, the present invention discloses a low-cost radiation shielding material containing recycled tire rubber and granulated iron or other metals.

2. Statement of the Problem

Nuclear radiation shielding for the storage, transport and disposal of spent nuclear fuels as well as nuclear waste from weapons production, for nuclear medicine, the space program, and other applications is a subject of considerable interest. Extensive research and development efforts are currently underway in this area to reduce costs and create methods for safe handling and transportation of radioactive materials and wastes to ensure worker and public safety.

The nation's inventory of spent nuclear fuel alone is in excess of 70,000 metric tons, generated over 40 years of nuclear power plant operations that have supplied 20% of the nation's electricity. Also, as environmental consequences, such as air pollutants and greenhouse gas emissions loom as ever greater concerns, it is highly probable that the portion of our energy generated by nuclear reactors will rise. Economic, effective means of handling and transporting nuclear materials are needed now and in the future.

Currently, there are plans in preparation to ship used nuclear fuel assemblies from 129 sites in 39 states in this country to a proposed permanent, deep geological repository in Yucca Mountain, Nev. (Nevada Test Site). The Department of Energy released its strategic plan for these shipments in November, 2003. The spent fuel rods still reside in storage casks in or near the reactor facilities where they were employed. One of the current concepts for shielding within the shipping casks proposes to use depleted uranium (U-238) oxide aggregates combined with binders that will enhance neutron shielding. U-238 is very effective in absorbing gamma rays. The binder materials under consideration include cementitious pastes, pyrolytic carbon and various polymers. The goal is to optimize shielding to maintain cask surface exposures at or below regulatory limits, and at the same time minimize weight and overall container size at economical costs.

Previously developed radiation shielding materials generally employ relatively expensive materials or require time-consuming means for manufacture. The prior art in this field includes U.S. Pat. No. 6,548,570 (Lange), U.S. Pat. No. 5,015,863 (Takeshima et al.) and U.S. Pat. No. 5,908,884 (Kawamura et al.). Kawamura et al. teaches the use of rubber in combination with very dense metals, such as tungsten or lead, but the process involves unvulcanized rubber that is subsequently vulcanized into a final product.

3. Solution to the Problem

In contrast to the prior art, the present invention utilizes ground scrap tire rubber, which is already vulcanized, and particles of inexpensive metals, such as granulated iron or steel. The use of recycled tire rubber provides a market for the cost-effective recycling of used tires. In addition, granulated iron or steel is inexpensive and is readily available as waste products from manufacturing processes. The resulting product provides effective shielding against nuclear radiation at lower cost and usually provides lower overall weight.

### SUMMARY OF THE INVENTION

This invention provides a radiation shielding material containing ground vulcanized rubber (e.g., scrap tire rubber), granulated or powdered iron or other metals of moderate cost, and a suitable binder (e.g., polyurethane or asphalt). In one embodiment, granulated metal is dispersed in the binder along with the ground rubber particles. The rubber particles can also be provided with a metallic coating, and then mixed with the binder. In addition to being very low cost, this material provides effective shielding against nuclear radiation and can be readily customized to meet the specific needs of wide variety of applications. The present material is also easily formable by molds into virtually any desired shape, with minimum labor costs.

These and other advantages, features, and objects of the present invention will be more readily understood in view of the following detailed description and the drawings.

### BRIEF DESCRIPTION OF THE DRAWINGS

The present invention can be more readily understood in conjunction with the accompanying drawings, in which:

FIG. 1 is a graph showing the maximum radial external surface dose rate as a function of the iron volume fraction for a transfer cask containing spent nuclear fuel using the present invention.

FIG. 2 is a graph showing the density of the shielding material as a function of the iron volume fraction.

FIG. 3 is a graph showing the dose rate as a function of the hydrogen-to-carbon ratio in the present invention.

FIG. 4 is a graph showing the variation in the granular compound density and iron weight fraction of the shielding material as a function of the iron volume fraction.

FIG. 5 is a graph showing a comparison of neutron energy deposition in tissue between conventional concrete shielding and the present invention.

FIG. 6 is a graph showing a comparison of neutron heating between conventional concrete shielding and the present invention.

FIG. 7 is a graph showing a comparison of secondary photon energy deposition in tissue between conventional concrete shielding and the present invention.

FIG. 8 is a graph showing a comparison of secondary photon heating between conventional concrete shielding and the present invention.

FIG. 9 is a graph showing a comparison of photon energy deposition in tissue between conventional concrete shielding and the present invention.

FIG. 10 is a graph showing a comparison of photon heating between conventional concrete shielding and the present invention.

### DETAILED DESCRIPTION OF THE INVENTION

The present invention discloses a radiation shielding material containing inexpensive metal particles (e.g., iron or steel) and ground vulcanized rubber (e.g., scrap tire rubber) bound in a matrix with a suitable binder. Powdered or ground iron or steel are common industrial byproducts which are generally recycled, but can be purchased in bulk granular form at nominal cost. Typical tires consist of both nature and synthetic rubbers, along with some carbon black and lesser constituents. The ground tire rubber can be separated from residual fiber and steel wire, if desired for a specific application. Ground tire rubber having a particle size of approximately 40 mesh is widely available from large number of grinding plants, and sells for modest prices, usually ranging from 15 to 20 cents per pound, FOB plant site. Polyurethane can be used as the binder. Low-cost asphalt (bitumen) might be another option as a binder, depending on environmental conditions, and is widely available at costs of about 10 to 12 cents per pound. Cement is another possible binder.

Given a particular radiation source to be shielded, the composition may be optimized and, as desired, molded or formed into a suitable shape or configuration. For example, it is anticipated that a metal content in the approximate range of 10% to 80% (volume fraction) would be suitable for a wide range of applications. The binder content could range between approximately 5% to 35% (volume fraction), with the balance of the composition being ground tire rubber. The present material can be employed in almost any scenario in which radioactive material is involved if the temperature is not excessive (i.e., below about 200° C.). This includes most nuclear waste forms or canisters, nuclear medical materials, and other environments where radiation shielding is required.

A mixer or blender can be employed to disperse the metal particles into the ground tire rubber. The binder is then added with further blending. This type of procedure is currently used in field of playground surfacing and is commonly know as a “poured in place” procedure. The binders are quite benign and only minimal worker protection is required. Additional metal particles can be disbursed in the mixture if the shielding requirements for a specific application mandate higher thermal or electrical conductivity. For example, waste fuels can generate high heat loads and therefore require shielding with higher thermal conductivity.

Optionally, the ground vulcanized rubber particles can be provided with a metallic coating. This can be in addition to, or instead of dispersing metallic particles in the binder. The coating can comprise any metallic material having suitable gamma-ray/x-ray shielding properties, such as lead, tungsten, bismuth, iron, or tantalum. The coating can be applied to the rubber particles by any of a number of known processes, such as physical vapor deposition or chemical vapor deposition. Optionally, at least some of the rubber particles can be also coated with neutron-absorbing materials, such as boron, B4C, borated stainless steel, cadmium, hafnium, gadolinium, erbium, europium, etc. to improve the effectiveness of the material in removing neutrons, especially for low-energy neutrons. These coated particles can be also used as aggregate and/or supplements to cement to produce a concrete with better radiation protection properties

In one embodiment, the rubber particles have diameters in a range from about 0.01 mm to 1 mm. Preferably, the rubber particles have diameters from about 0.5 mm to 1 mm. The metallic coating thickness can range from about 1-500 μm. The coated rubber particles can then be bonded together with a suitable binder. For example, this can be done by mixing the coated rubber particles with a binder and forming the resulting mixture into a desired shape.

The coating improves the distribution of metal within the shielding material. In particular, a thin metallic coating increases the surface area to volume ratio of metal in the shielding material in contrast to metal particles in the previous embodiment. This is anticipated to increase the absorption of incident radiation for a given weight of metal in the shielding material.

Although this coating creates a unitary particle structure to be mixed with the binder, it should be understood that the vulcanized rubber and metallic coating serve dual purposes. The rubber is more effective in attenuating/absorbing neutron radiation, while the metal coating is more effective in absorbing gamma radiation and x-rays.

The use of a single type of coated particle provides a number of advantages over the previous embodiment. It is simpler to select a suitable binder for a single type of particle, rather than having to cope with the different chemical and thermal characteristics of multiple particle types. In addition, the particles can be more readily made to have a uniform size, which creates more homogeneous shielding material. It may also increase the packing fraction of the particles and thereby increase the effectiveness of the shield material.

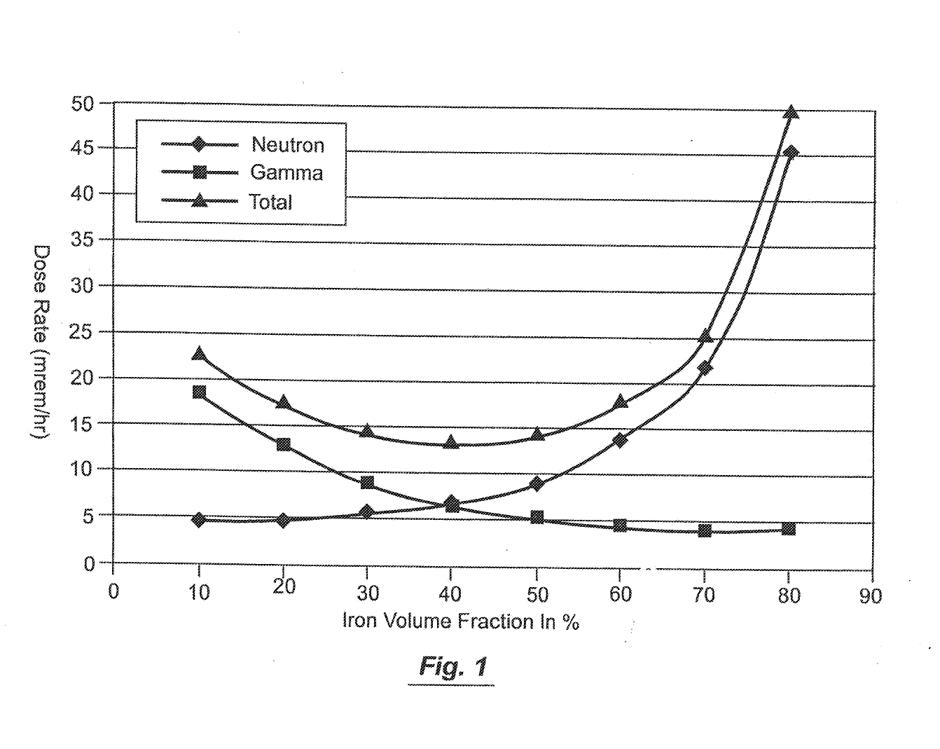

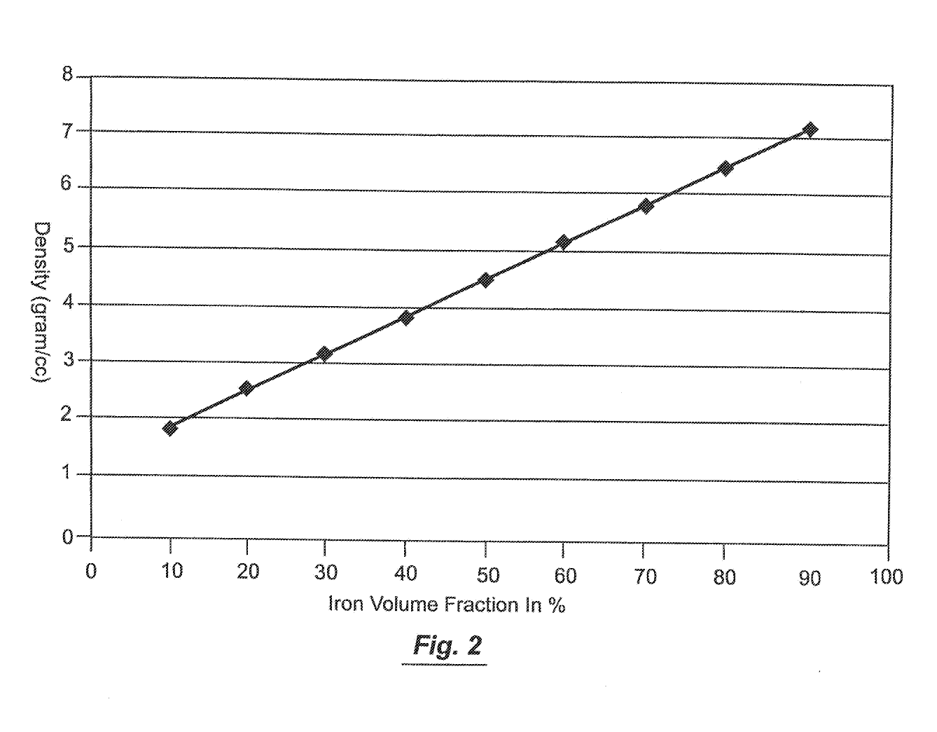

Transfer Cask Shielding. FIG. 1 is a graph presenting a sample calculation for use of the present invention in radiation shielding for a transfer cask containing spent nuclear fuel. In this example, the present material is employed as a substitute for a conventional shield consisting of lead and water contained within a stainless steel case. The conventional shield design is 23.5 cm in thickness. The sample calculation employs the same thickness, but varies the percentage of granulated iron in an iron-rubber blend. The optimum composition providing the greatest reduction in the surface dose rate is seen from FIG. 1 to be about 40% granular iron. FIG. 2 is a graph showing the density of the shielding material as a function of the iron volume fraction. In this calculation, the ground rubber is represented by a simple hydrocarbon of elemental carbon and hydrogen in the ratio of 1:2 (i.e., CH₂) with a density of 1.15 grams per cubic centimeter. The resulting minimum dose rate of about 24 mrem/hr on the outer surface is lower by a factor of 4.5 relative to the result obtained using lead and water as shielding of equal thickness. In order to achieve the same surface dose rate as the reference case, the shield thickness and weight can be reduced to approximately 40% to 50% of the reference case.

This example demonstrates the utilization of waste tire rubber consisting of a relatively high concentration of hydrogen and carbon elements mixed with a high-Z material such as iron to generate highly effective shielding material with a simple and cost-effective production process. It should also be pointed out that this material is very flexible and can be adjusted easily to various irregular shield shapes and configurations, and is especially suitable for wrapping pipes used to transfer nuclear waste or radioactive materials.

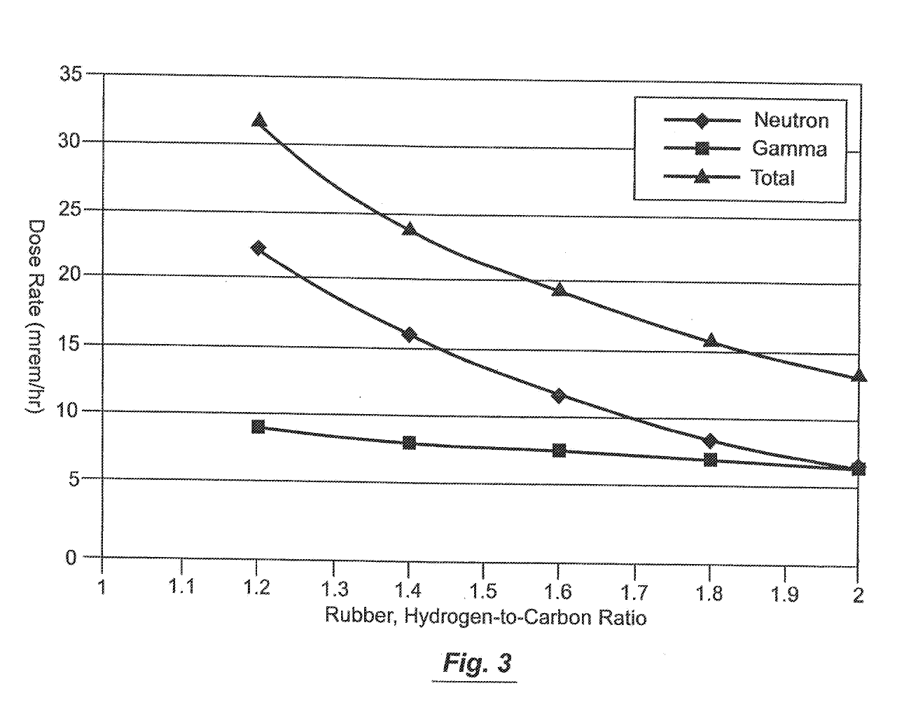

There are various compound compositions of tire rubber, but most of these can be characterized from the shielding point of view by different hydrogen-to-carbon ratios. The effect of this ratio on the shielding properties is given in FIG. 3 for an iron volume fraction of 40% (i.e., the optimum case). As can be seen from this graph, this ratio has a relatively small effect on the gamma attenuation, but a significant effect on the neutron moderation power. In most of the common tire rubber blends, the hydrogen-to-carbon ratio is around 1.8, as previously noted. The total dose rate increases only by about 18% relatively for a hydrogen-to-carbon ration of 2.0, mainly due to neutrons. In this preliminary calculation, we ignore all the impurity species existing in ordinary tire rubber, an effect that is estimated to be less than 5% and will have relatively little effect on the overall shielding properties.

The relationship between rubber volume fraction and weight fraction inside the compound material can be calculated directly from the following:

$$WeightFraction ( Rubber ) = \frac{1}{1 + \frac{{ρ}_{IRON}}{{ρ}_{RUBBER}} ( \frac{1}{VolumeFraction ( Rubber )} - 1 )}$$

$$and \text{:} WeightFraction ( Iron ) = 1 - WeightFraction ( Rubber )$$

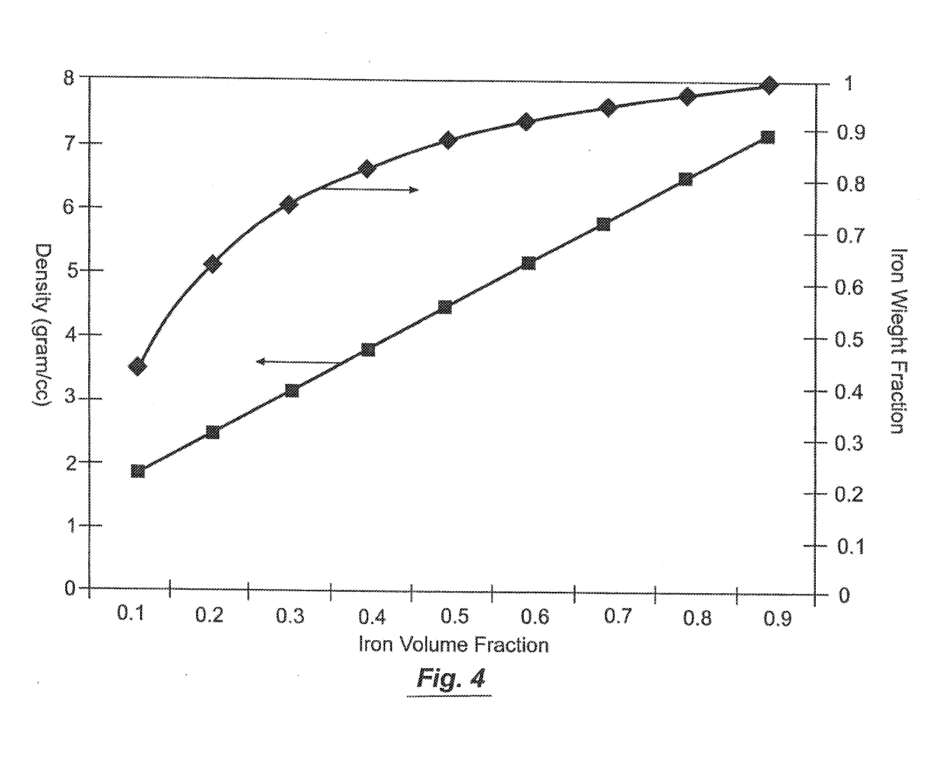

FIG. 4 is a graph showing the variation in the granular compound density and iron weight fraction of the shielding material as a function of the iron volume fraction.

The optimal embodiment of the present material for a specific application will vary with the precise nature of the nuclear materials to be shielded and the nature of the intended application. For example, protective suits to be worn by workers in a contaminated area require a more flexible shielding material (i.e., elastic, with a long fatigue life) than shielding intended to be fitted around piping or in shipping casks. For the example shown in FIG. 1, the curves indicate an optimal composition that is about 25% iron particles and 75% rubber plus binder for a 24 cm shield thickness. However, this is hardly desirable for protective suits or clothing. Thus, the thickness of the shielding material and the relative proportions of the recycled crumb rubber, metal powder, and binder can vary over a wide range to meet the specific needs of a given application. In addition, the type of metal powder and binder can be selected for each specific application.

Optionally, the present material could also include any of a number of dense metals in combination with, or as a substitute for iron. The concentration and the types of high-Z materials (e.g., Pb, Bi, W, Ta, or depleted uranium) can be tailored to the specific source term characteristic, i.e., the neutron and gamma source spectra and relative intensities between them. Solid metal hydrides (e.g., zirconium, titanium, lithium or yttrium hydride) could also be used in combination with, or as a substitute for iron for specific applications. However, these materials are likely to be more costly. It is also possible to further enhance the neutron shielding attenuation by adding a small amount of granular B₄C or B-10 to the iron-rubber compound.

Pipe Shielding. A second example demonstrating the powerful shielding properties of the present invention is that of shielding nuclear waste transfer pipes. Typically, these pipes are made of two concentric pipes, the nuclear waste carrier inner pipe and the encasement outer pipe. The pipes are made of carbon steel with a density of about 7.86 g/cm³. This inner pipe has an inside radius of 4.04 cm and a wall thickness of 0.40 cm. The outer pipe has an inside radius of 7.93 cm and a wall thickness of 0.49 cm. The outer pipe is also wrapped with very low density polyurethane foam insulation having a thickness of 5.08 cm. The two concentric pipes are buried at a depth of about 90 cm within compacted soil having a density of about 1.76 g/cm³ (Hanford soil). The calculated dose rate for this case is about 0.3 mrem/hr, which satisfies the dose rate limit of below 0.5 mrem/hr at 30.45 cm above the soil surface. In this case, we assume the main contributor to the dose rate is the Cs-137 isotope emitting photons in energy of 0.6621 MeV. The source volume density is about 1.07×10¹² photons per second per cubic centimeter.

In our simulation using MCNP5 code, the air gap between the pipes and the polyurethane insulation is replaced by shielding material containing 40% volume fraction of iron and 60% volume fraction of ground scrap tire rubber. The hydrogen-to-carbon ratio is assumed to be 1.8. The calculated results show that a soil depth of only 65 cm is sufficient to bury the two concentric pipes in order to meet the dose rate limit. The calculated dose rate is 0.45 mrem/hr. This example provide additional evidence of the versatility of this low-cost elastic shielding material, which can have a significant impact on the costs of constructing and assembling nuclear waste transfer pipelines. In addition, the present invention would reduce the costs of pipe maintenance by requiring less digging and providing easier access to the pipelines.

Concrete Shielding. The radiation protection properties of the present shielding material can also be compared against concrete, which is a common low cost construction-shielding material used for various shielding applications. In our simulation using MCNP5 code, comparisons were made for a neutron point isotropic source with the Watt fission spectrum. The total number on emitting neutrons was normalized to 10¹⁰ neutrons per second. The point source was placed at the origin of spherical shield configuration with a thickness of 50 cm. The point source is surrounded by air to a radius of 1 cm. Once again, the recycled rubber was simulated with a hydrogen-to-carbon ratio of 1.8 and a density of 1.15 gm/cc, blended with a 30% volume fraction of iron powder having a density of 7.785 gm/cc.

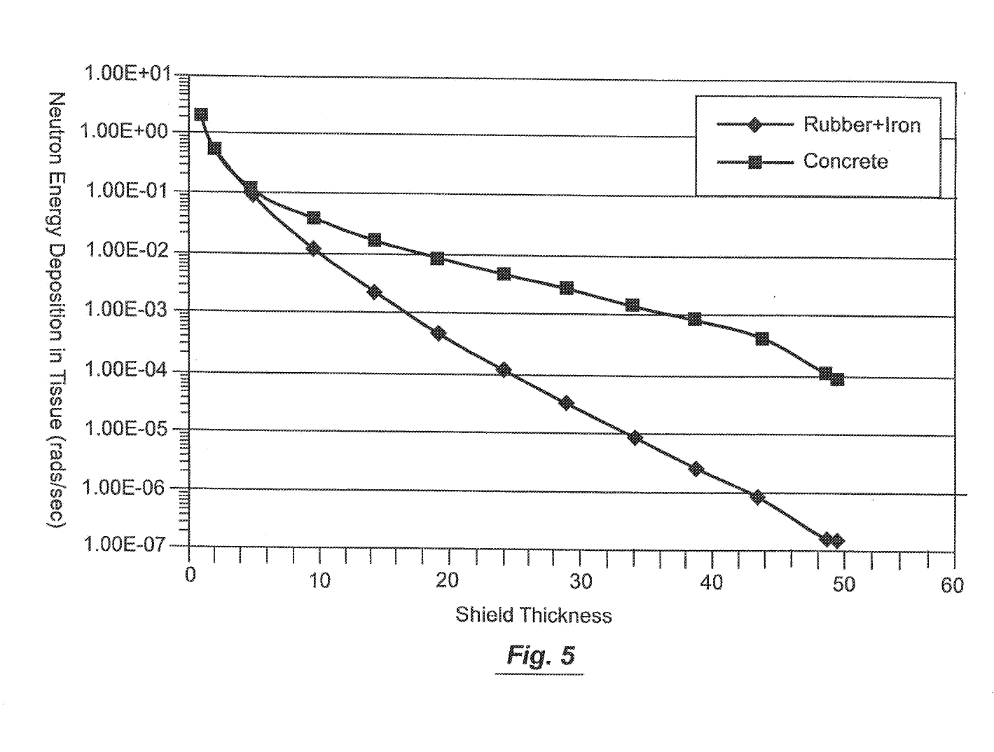

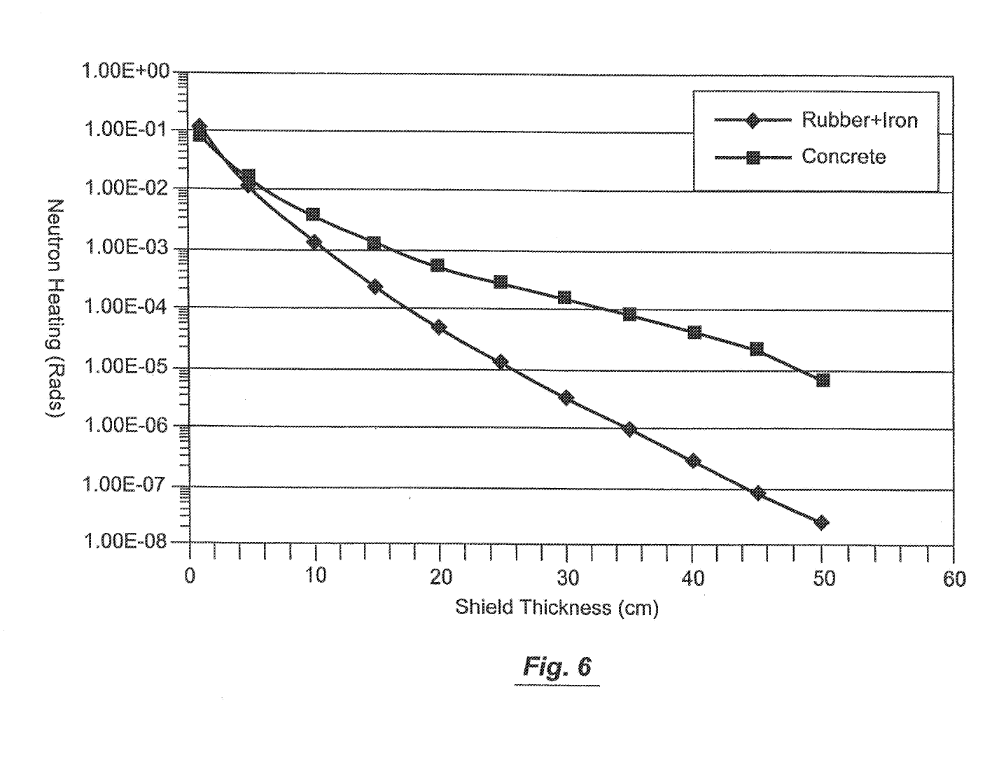

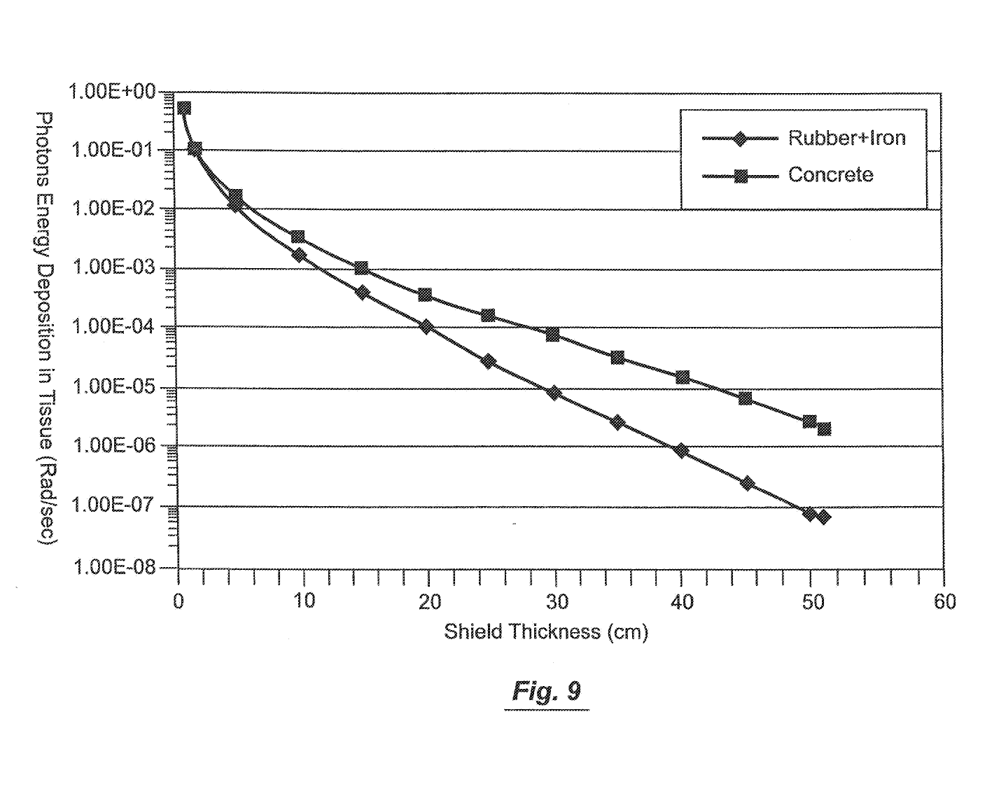

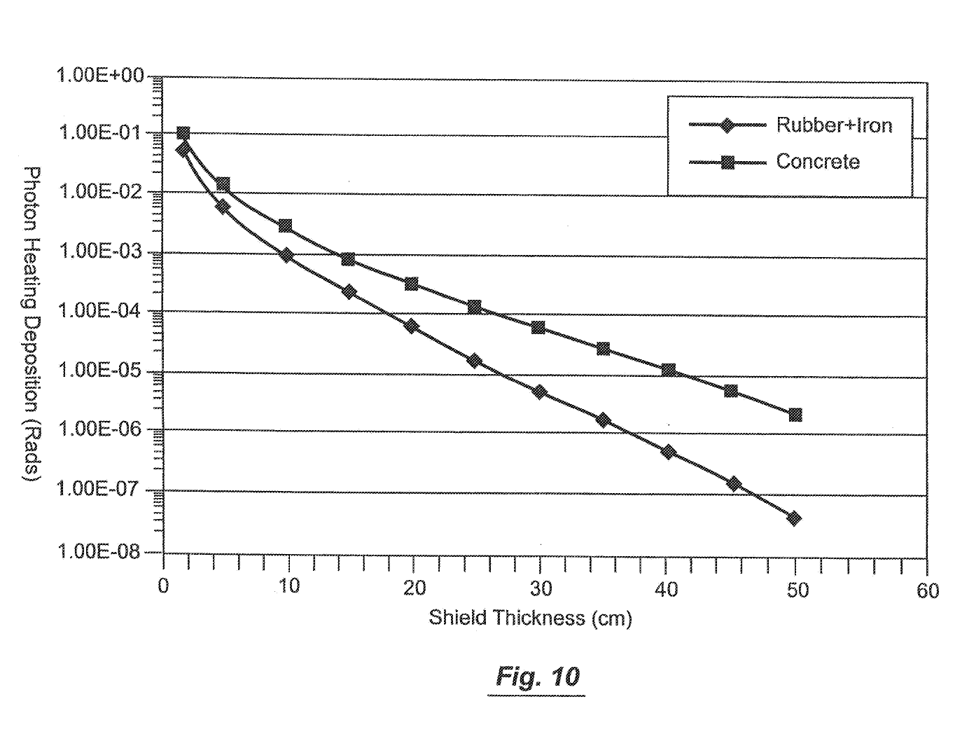

The computed results of energy deposition response for concrete and for the present invention are shown in FIGS. 5-10 and plotted as a function of shield thickness for energy deposition in biological tissue and in shield materials for neutrons and secondary photons induced by neutrons. As can be seen from these figures, a 50 cm shield made of recycled rubber and iron has a dose rate about 3 orders of magnitude lower than that of conventional concrete shielding. With the present invention, the thickness of the shield can be reduced by about 50% to provide the same attenuation as concrete. These results indicates that the present invention could compete with concrete even if its estimated production costs are almost double that of concrete.

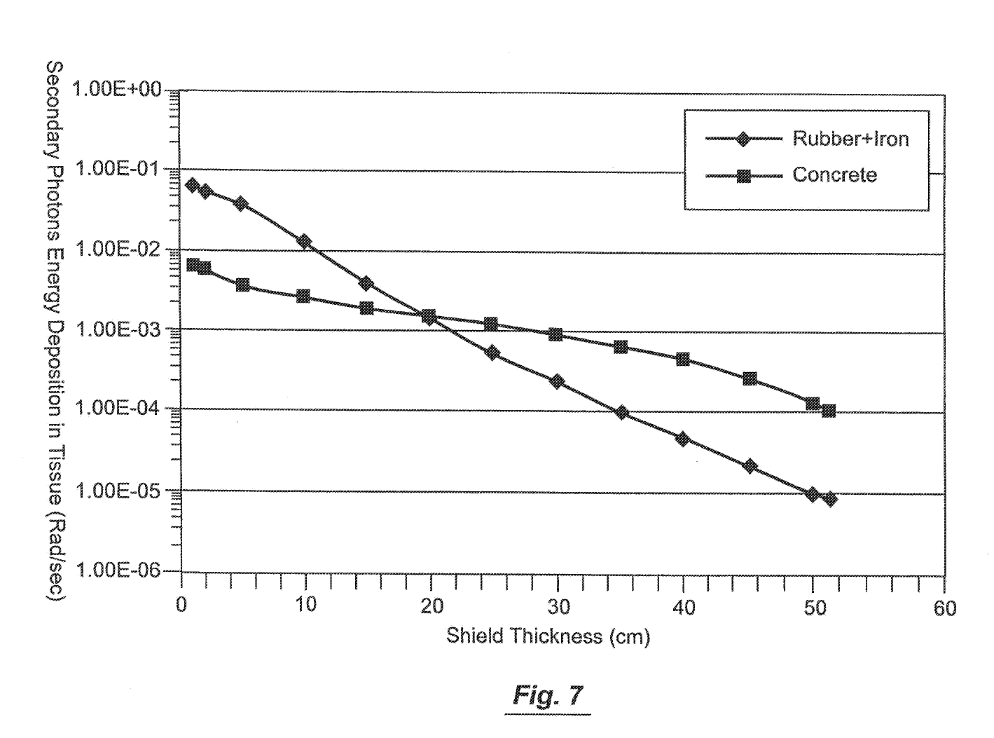

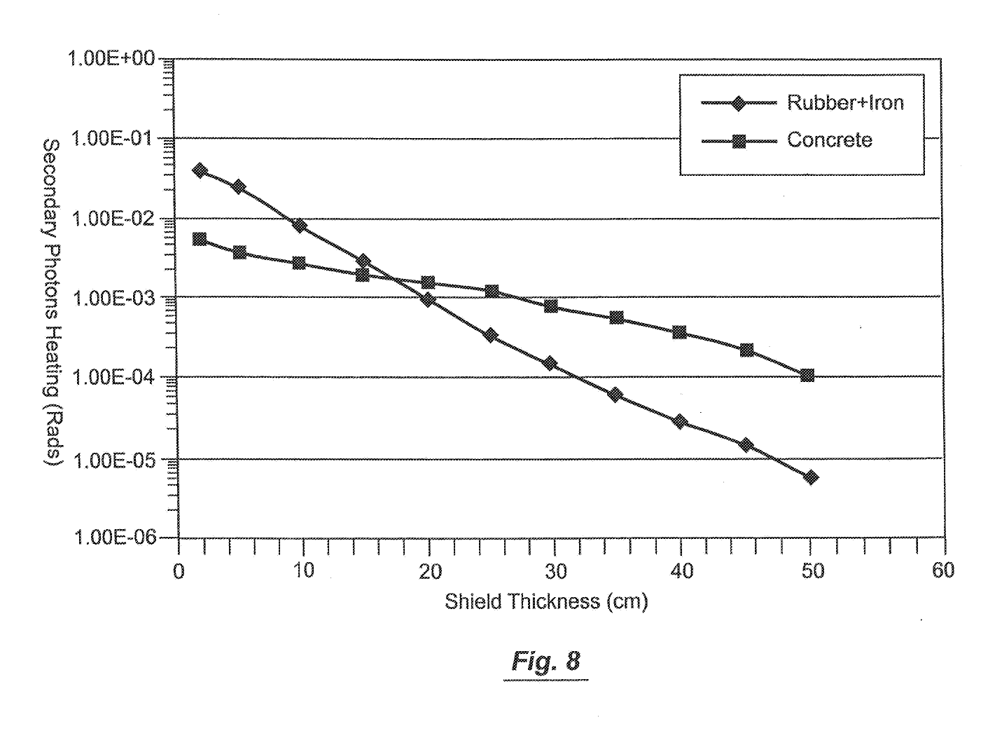

The relatively high concentration of iron powder in the present material is the source of the most of secondary photons generated due to absorption and inelastic scattering, but this effect is surpassed by attenuation of neutrons which reduces the production rate of secondary photons. Therefore, for a relatively small shield thickness, concrete produces less secondary photons than the present invention (see FIGS. 7 and 8).

Another example uses a Co-60 gamma (1.33 and 1.17 MeV) point source placed at the center of a spherical shield configuration in a similar geometrical configuration as the previous case. The photon source is again normalized to 10¹⁰ photons per second. Here again, the present material has superior shielding performance over the concrete for biological dose rate barrier and energy heating deposition. A shield thickness of 50 cm results in a dose rate that is two orders of magnitude lower than that of conventional concrete shielding, with significantly less heating energy deposition. This preliminary analysis gives us a good indication that the present invention can replace concrete shielding for certain application even if the production cost is double that of concrete.

Radiation Protective Garments. The present material could also be incorporated as shielding material within radiation protective garments. Our calculations show that the proposed radiation shielding material is better than lead in terms of grams/cm² for higher energy (hard) gamma ray spectrum and comparable to lead for a soft gamma ray spectrum. This material also provides very effective shielding against neutron radiation. The material has very good physical characteristics (such as flexibility) that make it easier to work with and handle than lead. Unlike lead, the present material is nontoxic and requires no special or restrictive conditions for disposal. In the fields of decontamination and decommissioning, the actual garment design is dependent on the radiation environment to which workers would be exposed. However, our preliminary analysis shows that it is possible to reduce radiation dose rates by 20% to 50% for a very hard radiation spectrum to a more moderate one, and that working time can be extended up to a factor of two.

Decontamination and decommissioning activities sometimes require intervention work within highly radioactive environments consisting of high radiation fields, but neutrons and gamma source, for which it is impossible or uneconomical to conduct needed activities by remote-control robotic systems. Most of the available commercial protective garments are effective against alpha particles and chemical aerosol or dust, but provide little, if any protection against neutrons and gammas from direct external radiation. The present invention is based on combining high-Z (e.g., iron, lead) with low-Z materials (e.g., high concentration of hydrogen and carbon atoms) in granular form into a single flexible material employing an appropriate binder. This flexible material can be sandwiched between two sheets of sealing material (e.g., nylon or polyethylene).

Radiation Shielding Material for Space Mission Applications. The present material also had potential application as a radiation shield material for long-term space missions to protect biological (astronauts) and electronic systems. Here again, the present invention is based on combining high-Z and low-Z materials in granular forms into a single material with an appropriate binder. The present invention allows a single shielding material to be used for both neutral and high-energy charged particles, with excellent radiation protection properties and with less associated weight than would be required if multiple layers of high-Z and low-Z materials were used alone.

These compound materials can be designed for optimum spatial distribution of the metal-to-rubber ratio by manufacturing various layers with different concentrations of the granular metal within the rubber. These layers can then be stacked and bonded together, which has the potential for further reduction in material weight for specific radiation sources and applications. Spacecraft can be subjected to two kinds of radiation sources, an external one consisting of charged particles in the trapped belts, galactic cosmic rays (GCRs), solar particle events (SPEs), and solar wind, and an internal one (onboard) from a nuclear reactor designed for propulsion or auxiliary power.

For any activity in space, the effects of external and internal radiation fields must be determined for biological systems (astronauts) and electronic systems in order to avoid damage to these systems and for reliable accomplishment of their missions. Therefore an appropriate shielding material should be evaluated for any specific spacecraft long-term mission design. Shielding materials can be a high cost factor in an overall system design, therefore multifunctional radiation protective materials (structural and shielding) are a critical key for cost-effective development of manned spacecraft.

The effectiveness of a shielding material is characterized by its ability to absorb the energy of the highly energetic particles within the shield material and to reduce (or if possible avoid) generation of secondary particles that may deteriorate the radiological situation. It is already well known and understood that hydrogen is the most effective element for absorbing high energy neutrons through the elastic collisions with minimum secondary particle effects. Therefore the most effective space radiation shielding material is one that contains high concentrations of hydrogen, but these materials often lack other properties required for structural integrity and gamma ray and charge particle attenuation. Hydrogen also has a low cross-section at high energies neutrons, so it can be particularly effective when used in conjunction with other materials with high inelastic cross-sections at high energies. Consequently, the inelastic scattering in the metal is complemented by elastic scattering in the hydrogen of the rubber, which is preferable combination for most high energetic particles. Various multifunctional candidate materials are suggested and have been studied in the past by NASA, such as the possibility of using liquid hydrogen and methane as both radiation protection and fuel simultaneously. Lithium hydride is a common shield material used for nuclear propulsion spacecraft. Various forms of polymeric materials have been suggested such as polyethylene, and polysulfone and polyetherimide also show good structural integrity. Graphite nanofibers heavily impregnated with hydrogen may be viable in the future, and represent multifunctional space structural materials. Finally, aluminum has long been a spacecraft material.

In contrast to the above-mentioned exotic materials that have been previously developed or are under development for radiation protection (generally employing relatively expensive materials or requiring time-consuming means for manufacture), our proposed materials are very simple to fabricate and are also very effective of high energetic neutron/gamma flux and other charged particles. These innovative shielding materials utilize vulcanized rubber (e.g., ground tire rubber) which contains hydrogen concentrations similar to that of polyethylene, along with embedded granulated metal and appropriate binder. Various granulated light and heavy metals can be considered for specific shielding and structural applications such as aluminum, iron, lead, tungsten, tantalum, depleted uranium and more. The possibility of using highly-enriched hydride metal such as ZrHₓ to enhance hydrogen concentration with good structure integrity is also a possibility.

In the past, low cost binders were explored for this process, such as polyurethane, latex etc. but other types of binders could be used in these compound materials depending on the mechanical and physical properties requirements. In addition to being very low cost and providing effective shielding, the materials can be readily customized to meet the specific needs of a wide variety of applications. The present material is also easily formable by molds into virtually any desired shape, with minimal labor costs. These compound materials can be easily designed for optimum spatial distribution of the metal-to-rubber ratio by manufacturing various layers with different concentrations of the granular metal within the rubber. These layers can then be stacked and bonded together.

For spacecraft applications, off-gassing can be of concern as it relates to the degradation of the material and to the contamination of the spacecraft environment. Condensation of off-gassed materials represents a potentially serious problem, as does the presence of gaseous impurities in enclosed air spaces. Off-gas products emanate primarily from the binder, and will depend on the choice of binder employed. Therefore, off-gassing can be minimized by careful selection of an appropriate binder and by greater compression during fabrication to further reduce air voids in the material.

In summary, the present radiation protection materials show attenuation characteristics superior to those of an ordinary single-type material used in spacecraft for a wide range of particles types and spectrum. These compound materials, which utilize readily available components, can be used both for biological and electronic device protection against direct GCR ion particles as well as against secondary cascade particles (neutrons and gammas) with less weight and with cost effective methods of production and design. Due to high contents of hydrogen and carbon, the present compounds generate less secondary particles than other common high-Z materials used for electronic device radiation protection. Preliminary mechanical tests indicate that the present compounds have reasonable strength if the appropriate amount of binder is used. The recommended weight fraction of binder is in the range of about 25-30% for the 50% weight fraction iron case.

The above disclosure sets forth a number of embodiments of the present invention described in detail with respect to the accompanying drawings. Those skilled in this art will appreciate that various changes, modifications, other structural arrangements, and other embodiments could be practiced under the teachings of the present invention without departing from the scope of this invention as set forth in the following claims.

I claim:

1. A method for producing a radiation shielding material comprising:
grinding scrap tires to produce vulcanized rubber particles;
coating the rubber particles with a metal;
mixing the coated rubber particles with a binder; and
forming the resulting mixture into a desired shape for radiation shielding material.

2. The method of claim 1 further comprising mixing granulated metal with the binder and coated rubber particles.

3. The method of claim 2 wherein the granulated metal comprises iron.

4. The method of claim 1 wherein the binder comprises polyurethane.

5. The method of claim 1 wherein the binder comprises asphalt.

6. The method of claim 1 wherein the metallic coating comprises lead.

7. The method of claim 1 wherein the metallic coating comprises tungsten.

8. The method of claim 1 wherein the metallic coating comprises bismuth.

9. The method of claim 1 wherein the metallic coating comprises tantalum.

10. The method of claim 1 wherein the metallic coating comprises iron.
